(19) United States
(12) Patent Application Publication
(10) Pub. No.: US 2021/0335681 A1
(43) Pub. Date: Oct. 28, 2021

(54) CERAMIC STACKED SEMICONDUCTOR PACKAGE HAVING IMPROVED ANTI-HUMIDITY AND RELIABILITY AND METHOD OF PACKAGING CERAMIC STACKED SEMICONDUCTOR

(71) Applicant: Electronics and Telecommunications Research Institute, Daejeon (KR)

(72) Inventors: Hyun Gyu JANG, Daejeon (KR); Dong Yun JUNG, Daejeon (KR); Doo Hyung CHO, Daejeon (KR); Kun Sik PARK, Daejeon (KR); Jong Won LIM, Daejeon (KR)

(73) Assignee: Electronics and Telecommunications Research Institute, Daejeon (KR)

(21) Appl. No.: 17/217,433

(22) Filed: Mar. 30, 2021

(30) Foreign Application Priority Data
Apr. 27, 2020 (KR) 10-2020-0051086
Jun. 30, 2020 (KR) 10-2020-0080610

(51) Int. Cl. H01L 23/15; H01L 25/065; H01L 23/31; H01L 21/768; H01L 23/538; H01L 21/48

(52) U.S. Cl. CPC H01L 23/15; H01L 25/0657; H01L 23/31; H01L 23/5386; H01L 23/5384; H01L 21/486; H01L 21/76877; H01L 21/76802

(57) ABSTRACT

A ceramic stacked semiconductor package and a method of packaging a ceramic stacked semiconductor is disclosed. Inner walls of junctions are formed between ceramic layers and a molding resin to have a non-uniform boundary shape (e.g., Z shape, an uneven shape, a zigzag shape, etc.) so that bonding areas and lengths of the molding resin and the ceramic layers are increased, and thus adhesion is improved and movement paths of moisture are increased, thereby improving anti-humidity property and reliability of the semiconductor package. Further, by arranging via-holes at different positions for each layer so as not to overlap each other between the layers, movement paths of moisture passing through the via-holes are increased, and thus the anti-humidity property and reliability of the stacked package are additionally improved.

### CROSS-REFERENCE TO RELATED APPLICATION

This application claims priority to and the benefit of Korean Patent Applications No. 10-2020-0051086 filed on Apr. 27, 2020 and No. 10-2020-0080610 filed on Jun. 30, 2020, the disclosure of which are incorporated herein by reference in their entirety.

### BACKGROUND

### Field of the Invention

The present invention relates to a semiconductor package, and more particularly, to a ceramic stacked semiconductor package having anti-humidity property and reliability and having improved heat dissipation characteristics, and a method of packaging a ceramic stacked semiconductor.

### Discussion of Related Art

Recently, high-power applications used in fields such as electric vehicles and wireless power transmission are increasing. In the case of such applications, a large amount of heat is generated and, accordingly, research on wide bandgap (WBG) semiconductor devices using silicon carbide (SiC) or gallium oxide (GaO) having low loss at high temperature has been actively progressing. Further, due to an increase in applications that require high reliability such as autonomous vehicles, communication, power, and sensor elements constituting the application are required to have high reliability. For such applications, many studies are also being conducted in the field of semiconductor packages to maintain characteristics of semiconductor devices and improve reliability.

In the case of the conventional power semiconductor package, for heat dissipation, a power semiconductor is soldered to a large leadframe is molded with a resin such as an epoxy mold compound (EMC) to have insulation and anti-humidity properties, like a TO-type package. However, in the above method, due to a large volume of the package, there are restrictions on downsizing the applications. Accordingly, recently, surface-mount device (SMD) type power semiconductor packages have been released instead of the conventional TO-type packages. However, since the packages have a low thermal conductivity of an EMC, there is a limit to packaging a power semiconductor for several tens of amperes.

Currently, ceramic-based packages have been in the spotlight as packages for power semiconductors due to their high heat dissipation efficiency. In addition, since cavities may be easily formed in ceramic stacked semiconductor packages, a bonding length may be shortened, thereby minimizing parasitic components.

However, as a disadvantage, when a semiconductor device is placed in a cavity for ceramic packaging and an EMC for device protection fills the cavity, junctions are generated between a ceramic material and the EMC. Under high temperature and humidity conditions, cracks are generated in the junctions generated between the ceramic material and the EMC, moisture enters a gap therebetween, and thus the characteristics of the semiconductor device are degraded. In addition, when power is applied to internal electrodes, electric potential difference occurs between the electrodes, and dendritic defects (hereinafter, referred to as “dendrites”) are generated in the ceramic stacked semiconductor package, thereby increasing a leakage current of the package.

### SUMMARY OF THE INVENTION

The present invention is directed to providing a package structure, in which, when a ceramic-based stacked package is used for manufacturing a semiconductor package to improve heat dissipation characteristics, the generation of the above-described dendrites are suppressed so that anti-humidity and reliability of the package are improved, and a method of packaging the semiconductor.

According to an aspect of the present invention, there is provided a semiconductor package. In manufacturing the semiconductor package, when ceramic layers are stacked using a ceramic-based stacked package to improve heat dissipation characteristics, inner walls of junctions in the package are formed between the ceramic layers and a molding resin to have a non-uniform boundary shape (e.g., Z shape, an uneven shape, a zigzag shape, etc.) so that bonding areas and lengths of a resin (e.g., epoxy, silicone, urethane, etc.) used as a molding material and the ceramic layers are increased, and thus adhesion is improved and movement paths of moisture are increased, thereby improving anti-humidity property and reliability of the semiconductor package.

Further, by arranging via-holes at different positions for each layer so as not to overlap each other between the layers, movement paths of moisture passing through the via-holes are increased, and thus anti-humidity property and reliability of the stacked package are additionally improved.

Furthermore, by forming the via-holes for each layer to have multiple different diameters, bonding areas and lengths of the ceramic layers and the via-holes are increased, and degradation of characteristics of the semiconductor device and generation of dendrites, which are caused by moisture, may be prevented. Accordingly, anti-humidity property and reliability of the ceramic stacked package may be additionally secured.

The above-described configurations and operations of the present invention will become more apparent from embodiments described in detail below with reference to the drawings.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is an exploded view of a conventional ceramic stacked semiconductor package;

FIG. 2 is a three-dimensional view of a conventional ceramic stacked semiconductor package;

FIG. 3 is a cross-sectional view taken along line X-X′ of FIG. 2;

FIG. 4 is a cross-sectional view of a ceramic stacked semiconductor package in a state in which a semiconductor device is packaged;

FIG. 5 is a cross-sectional view for describing a problem of a ceramic stacked semiconductor package;

FIG. 6 is an exemplary view of dendrites generated in a ceramic stacked semiconductor package;

FIG. 7 is a cross-sectional view of a ceramic stacked semiconductor package in which junctions have non-uniform boundary-shaped inner walls;

FIG. 8 is a cross-sectional view of a ceramic stacked semiconductor package in which junctions have non-uniform boundary-shaped inner walls according to another embodiment;

FIG. 9 is an exemplary view illustrating via-holes having different diameters in ceramic layers; and

FIG. 10 is a cross-sectional view of a power converter module manufactured by a method of packaging a ceramic stacked semiconductor according to the present invention.

### DETAILED DESCRIPTION OF EXEMPLARY EMBODIMENTS

Advantages and features of the present invention and methods for achieving them will be made clear from embodiments described in detail below with reference to the accompanying drawings. However, the present invention may be embodied in many different forms and should not be construed as being limited to the embodiments set forth herein. Rather, these embodiments are provided so that this disclosure will be thorough and complete and will fully convey the scope of the present invention to those of ordinary skill in the technical field to which the present invention pertains. The present invention is defined by the claims.

Meanwhile, terms used herein are for the purpose of describing the embodiments and are not intended to limit the present invention. As used herein, the singular forms include the plural forms as well unless the context clearly indicates otherwise. The term “comprise” or “comprising” used herein does not preclude the presence or addition of one or more other elements, steps, operations, and/or devices other than stated elements, steps, operations, and/or devices.

Hereinafter, exemplary embodiments of the present invention will be described in detail with reference to the accompanying drawings. In describing the embodiments, the detailed description of a related known configuration or function will be omitted when it obscures the gist of the present invention.

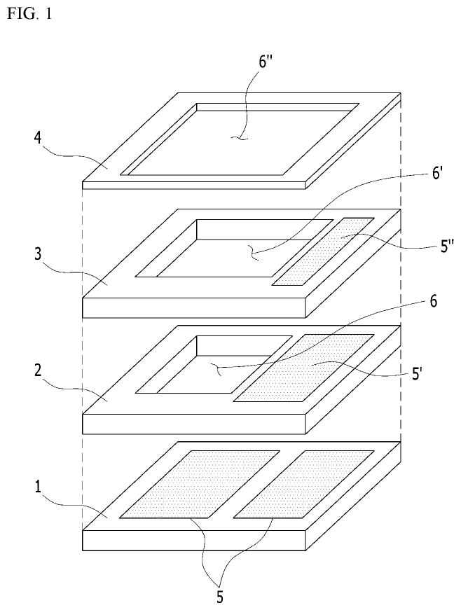

FIG. 1 is a three-dimensional exploded view of a general ceramic stacked semiconductor package. A first ceramic layer 1 is a layer on which a semiconductor is bonded and mounted, and internal electrodes 5 are formed thereon. In a second ceramic layer 2 to a fourth ceramic layer 4, grooves or cavities 6, 6′ and 6″, into which semiconductor devices are mounted, are formed and internal electrodes 5′ and 5″ for interlayer connection are formed.

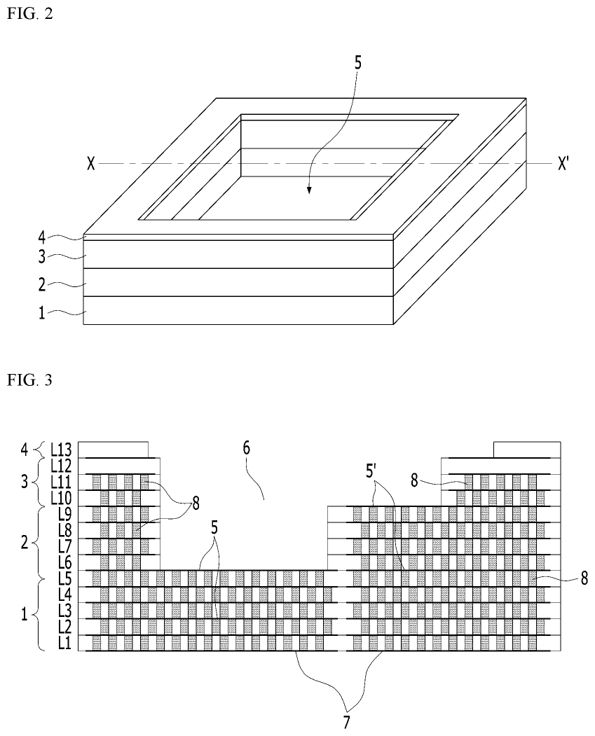

FIG. 2 illustrates a three-dimensional view illustrating a structure in which the ceramic layers of FIG. 1 are stacked. The ceramic layers are stacked and then sintered at a temperature of about 900° C. to manufacture a package. Hereafter, in detailed descriptions of the structure of the ceramic stacked semiconductor package according to the present invention, it is assumed that cross-sectional views to be illustrated below are all cross-sectional views taken along line X-X′ illustrated in FIG. 2.

FIG. 3 is a cross-sectional view of the ceramic stacked semiconductor package according to the present invention and is a cross-sectional view corresponding to the cross-sectional view taken along line X-X′ of FIG. 2. In the ceramic stacked semiconductor package, a plurality of ceramic layers L1 to L13 are stacked as illustrated in FIG. 3. A manufacturing process of the ceramic stacked semiconductor package is as follows.

In each ceramic layer, a part of the ceramic layer is removed by a punching process to form a groove or cavity 6, which is a space in which the semiconductor device will be placed. Next, a punching process and a metal filling process for forming a plurality of via-holes 8 which electrically connect internal electrodes 5 and 5′ and external electrodes 7 to each other are performed and, finally, the internal electrodes 5 and 5′ and the external electrodes 7 are formed by a screen-printing method. Thereafter, as illustrated in FIGS. 1 and 2, all the ceramic layers are sequentially stacked and then sintered to complete the ceramic stacked semiconductor package. Here, by arranging the via-holes 8 at different positions so as not to overlap each other between the layers, movement paths of moisture passing through the via-holes 8 are increased, thereby securing anti-humidity and reliability of the ceramic stacked semiconductor package.

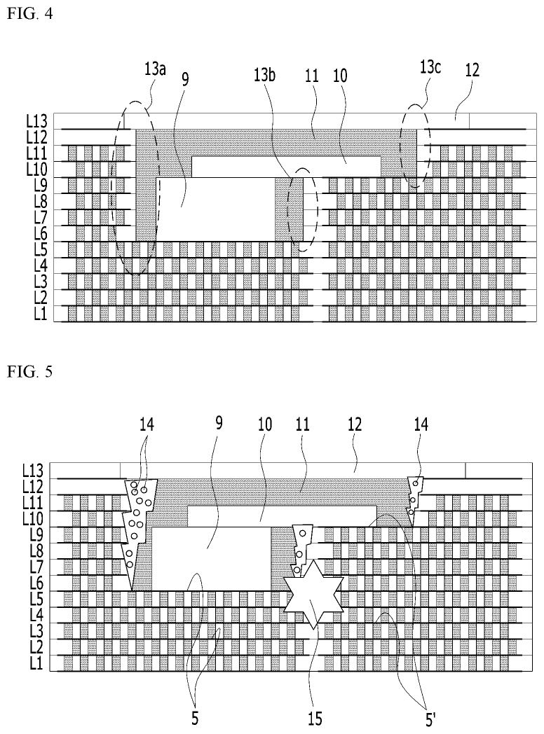

FIG. 4 illustrates a state in which a semiconductor device 9 is mounted in the cavity and then the ceramic stacked semiconductor package is filled with a molding resin 11 to perform packaging. Here, the semiconductor device 9 is assumed to Schottky barrier diode (SBD).

Referring to FIGS. 3 and 4, a lower surface of the SBD 9 is a cathode electrode and bonded to a predetermined electrode (e.g., the internal electrode 5) of a ceramic substrate by soldering, and an upper surface of the SBD 9 is an anode electrode and electrically connected to a predetermined electrode (e.g., the internal electrode 5′) by clip bonding 10 made of Cu, etc. Next, the space of the cavity 6 in which the semiconductor device 9 is placed is filled with the molding resin 11 such as an epoxy mold compound (EMC) to protect the SBD 9. Finally, the SBD bearing ceramic stacked semiconductor package is sealed using a case 12 made of a metal such as Al, etc.

In the case of FIG. 4, junctions located between the ceramic layers and the molding resin 11 have three parts, that is, a first junction 13a located on a left side surface of the cavity 6, a second junction 13b located on a side surface of a bottom of the cavity 6, and a third junction 13c located on a side surface of the right of the cavity 6. When the junctions 13a, 13b, and 13c are formed between the ceramic layers and the molding resin 11 as inner walls having a uniform and smooth boundary, the following problems occur.

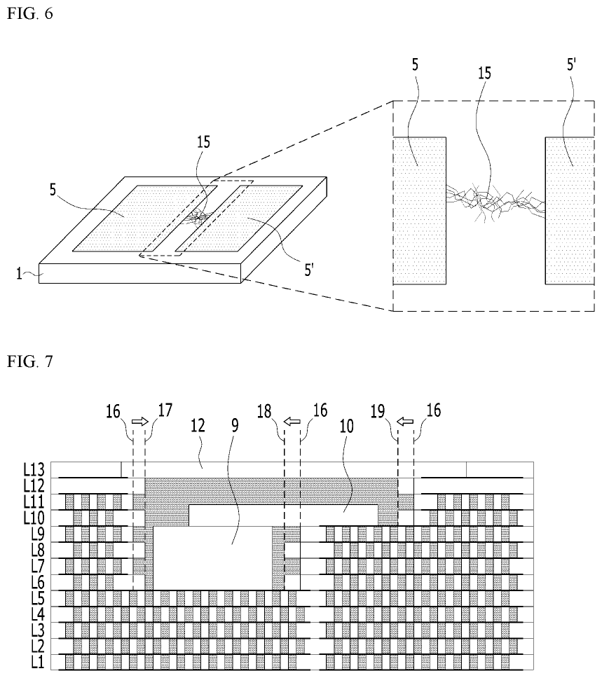

FIGS. 5 and 6 are views describing the problems that occur due to the junctions having the uniform and smooth boundary-shaped inner walls. Under high temperature and humidity conditions, cracks are generated in the junctions 13a, 13b, and 13c between the ceramic layers and the molding resin 11 as illustrated in FIG. 5 and moisture 14 enters a gap therebetween, and thus the characteristics of the semiconductor device 9 are degraded. In addition, when electricity is applied to the internal electrodes 5 and 5′, electric potential difference occurs between the electrodes and dendrites 15 are generated due to the moisture 14, thereby lowering reliability, such as increasing a leakage current of the semiconductor package. In FIG. 6, an example in which dendrites are generated in a first ceramic layer 1 is illustrated. An example is illustrated in which voltages having different polarities are supplied between the internal electrode 5 and 5′ so that electric potential difference occurs therebetween and the introduced moisture 14 (see FIG. 5) is added thereto so that the dendrites 15 are generated in the ceramic layers between the electrodes 5 and 5′.

FIG. 7 illustrates an embodiment in which the uniform boundary-shaped inner walls of the junctions 13a, 13b, and 13c between the ceramic layers and the molding resin 11 described in FIG. 4 are improved in order to solve the above problem. In the present embodiment, the inner walls of the junctions 13a, 13b, and 13c are formed to have a non-uniform boundary shape such as a Z shape, an uneven shape, or a zigzag shape, but some layers of the ceramic layers constituting the stacked body have a shape (inward expandable type) that extends toward an interior of the package.

In the first junction 13a between the ceramic layers and the molding resin 11, ceramic layers L6, L8, L10, and L12 extend to an inside 17 of the package (i.e., toward the semiconductor device 9) from the existing positions 16. In the second junction 13b, the ceramic layers L6 and L8 extend to a left side 18 from the existing positions 16. In the third junction 13c, the ceramic layers L10 and L12 extend to a left side 19 (i.e., toward the molding resin 11). Therefore, the non-uniform boundary-shaped inner walls are formed. Here, it has been described that every other ceramic layer extends to the inside of the package to form the non-uniform boundary-shaped inner walls, but the present invention is not limited thereto. For example, every two ceramic layers may extend inward, or arbitrary ceramic layers may irregularly extend inward.

As described above, by forming the inner walls of the junctions between the ceramic layers and the molding resin 11 in the package in a non-uniform boundary shape such as Z shape, an uneven shape, or a zigzag shape, bonding areas and lengths of the ceramic layers and the molding resin 11 may be increased, and degradation of the characteristics of the semiconductor device and generation of the dendrites, which are caused by moisture, may be fundamentally prevented. Accordingly, anti-humidity property and reliability of the ceramic stacked package may be secured. In addition, as described above, by arranging all the via-holes 8 at different positions for each layer so as not to overlap each other between the layers, movement paths of the moisture passing through the via-holes 8 are increased, and therefore the anti-humidity property and reliability of the stacked package may be additionally secured.

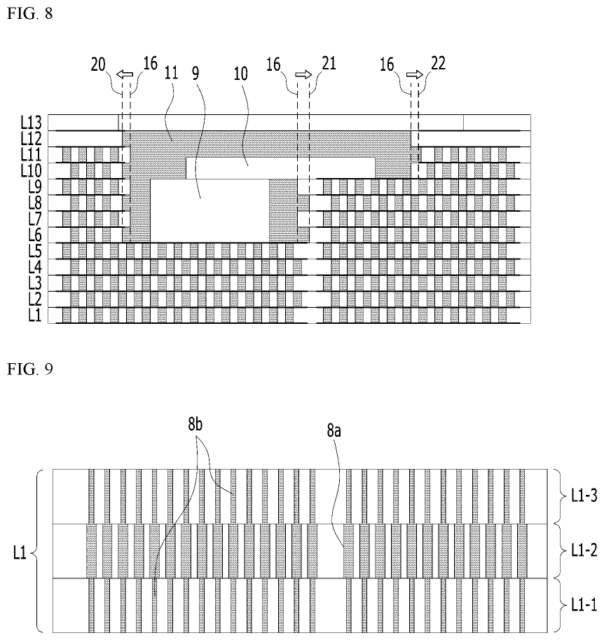

FIG. 8 is a view describing another embodiment in which the uniform boundary-shaped inner walls of the junctions 13a, 13b, and 13c between the ceramic layers and the molding resin 11 described in FIG. 4 are improved in order to solve the above-described problem. Similar to the embodiment of FIG. 7, in the present embodiment, the inner walls of the junctions 13a, 13b, and 13c are formed to have a non-uniform boundary shape, but some layers of the ceramic layers constituting the stacked body have a shape (outward shortened type) that are shortened toward an exterior of the package.

In the present embodiment of having the outward shortened type, in the first junction 13a, ceramic layers L6, L8, L10, and L12 are shortened toward an outside 20 of the package from the existing positions 16. In the second junction 13b, the ceramic layers L6 and L8 are shortened toward a right side 21 from the existing positions 16. In the third junction 13c, the ceramic layers L10 and L12 are shortened toward a right side 22 (i.e., a direction away from the molding resin 11). Thus, the inner walls of the junctions are formed to have a non-uniform boundary shape. Here, it also has been described that every other ceramic layer is shortened to form the non-uniform boundary-shaped inner walls, but the present invention is not limited thereto.

Like the embodiment of FIG. 7, in the present embodiment, by forming the inner walls of the junctions between the ceramic layers and the molding resin 11 in the package in a non-uniform boundary shape, bonding areas and lengths of the ceramic layers and the molding resin 11 may be increased, and degradation of the characteristics of the semiconductor device and generation of the dendrites, which are caused by moisture, may be fundamentally prevented. Accordingly, anti-humidity and reliability of the ceramic stacked package may be secured. In addition, by arranging all the via-holes 8 at different positions for each layer so as not to overlap each other between the layers, movement paths of the moisture passing through the via-holes 8 are increased and thus anti-humidity property and reliability of the stacked package may be additionally secured.

FIG. 9 illustrates an embodiment for additionally improving anti-humidity property of a ceramic stacked semiconductor package. A certain ceramic layer (e.g., L1) is manufactured by stacking several ceramic sheets L1-1 to L1-3. When punching and metal filling processes are performed to form via-holes in the layer L1, via-holes 8b having a small diameter, via-holes 8a having a large diameter, and via-holes 8b having a small diameter are formed in the ceramic sheets L1-1 to L1-3, respectively; the ceramic sheets are stacked, and thus the via-holes having different diameters are formed in the ceramic layer L1, as illustrated in FIG. 9. As a result, bonding areas and lengths of the ceramic layer and the via-holes may be increased, and degradation of characteristics of the semiconductor device and generation of dendrites, which are caused by moisture, may be prevented. Accordingly, anti-humidity property and reliability of the ceramic stacked package may be additionally secured.

The ceramic stacked semiconductor packaging technique of the present invention described above is applicable to individual electrical elements (e.g., active elements such as a transistor (TR), integrated circuit (IC), etc., or passive elements such as an inductor, resistor, capacitor, etc.). In addition, the ceramic stacked semiconductor package technique of the present invention is applicable to an electric circuit board (e.g., printed circuit board (PCB)) on which electrical elements such as active elements and/or passive elements are mounted.

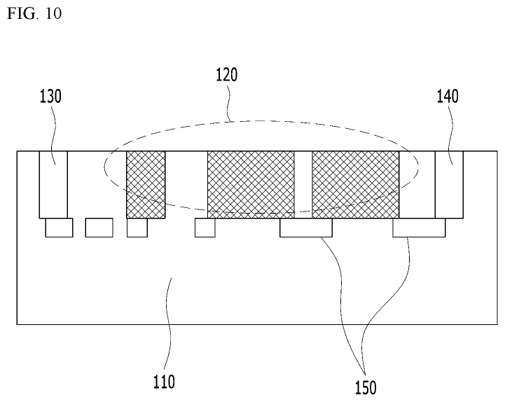

FIG. 10 is a cross-sectional view of a power converter module (or circuit board) manufactured by a method of packaging a ceramic stacked semiconductor according to the present invention. It illustrates an example in which a circuit board for a power converter module such as a buck converter or a boost converter is fabricated on a ceramic substrate by applying the ceramic stacked semiconductor packaging technique of the present invention. Circuit patterns 150 are formed on a ceramic substrate 110, and electrical elements 120 are mounted thereon, and thus a power converter capable of receiving power through an input port 130 and outputting a desired voltage and current through an output port 140 may be formed. Here, the electrical elements 120 themselves may also be manufactured using the ceramic stacked semiconductor package technique of the present invention.

For the circuit board, the same material and manufacturing method as the ceramic stacked semiconductor package may be used. That is, the cavities are formed in the ceramic substrate 110 using the same manufacturing method as the ceramic stacked semiconductor package, the metal circuit patterns 150 are formed by a screen-printing method, the input port 130, the output port 140, and the active and/or passive elements 120 which are manufactured using the ceramic stacked semiconductor package are formed and are electrically connected to each other, and thus the ceramic substrate 110 such as the power converter module of FIG. 10 may be manufactured. By applying the ceramic stacked semiconductor packaging technique of the present invention to the circuit boards as well as the electrical elements, a total volume of the power converter may be reduced, power density may be increased, and generation of dendrites may be prevented.

The semiconductor package according to the present invention uses a ceramic-based package having high heat dissipation to be suitable for a semiconductor device package that generates a large amount of heat. Further, when ceramic layers are stacked, inner walls of junctions between the ceramic layers and a molding resin (e.g., EMC) in a package are formed to have a non-uniform boundary shape, and thus bonding strength and bonding lengths of the ceramic layers and the molding resin can be increased so that anti-humidity property can be improved. As a result, reliability of the semiconductor package can be improved.

Further, conventionally, concave grooves, irregularities, or intaglio patterns that are used to improve the anti-humidity property of the package should be formed by molding or laser beam machining. However, in the present invention, an inside of the ceramic layer is partially removed to make inner walls have a non-uniform boundary shape, and thus bonding areas and lengths of the ceramic layers and a molding resin can be freely changed at a relatively low cost so that products can be diversified.

Although the present invention has been described in detail above with reference to the exemplary embodiments, those of ordinary skill in the technical field to which the present invention pertains should be able to understand that various modifications and alterations can be made without departing from the technical spirit or essential features of the present invention. Therefore, it should be understood that the disclosed embodiments are not limiting but illustrative in all aspects. The scope of the present invention is defined not by the above description but by the following claims, and it should be understood that all changes or modifications derived from the scope and equivalents of the claims fall within the scope of the present invention.

What is claimed is:

1. A ceramic stacked semiconductor package comprising:
a stacked body in which a plurality of ceramic layers is stacked;
via-holes through which the ceramic layers are connected to each other;
a molding resin with which an inside of the stacked body is filled; and
junctions formed between the stacked ceramic layers and the molding resin,
wherein the junctions between the ceramic layers and the molding resin have inner walls formed in a non-uniform boundary shape.

2. The ceramic stacked semiconductor package of claim 1, wherein, in the inner walls of the junctions having the non-uniform boundary shape, at least one layer of the stacked ceramic layers extends toward the molding resin.

3. The ceramic stacked semiconductor package of claim 1, wherein, in the inner walls of the junctions having the non-uniform boundary shape, at least one layer of the stacked ceramic layers is shortened in a direction away from the molding resin.

4. The ceramic stacked semiconductor package of claim 1, wherein, in the inner walls of the junctions having the non-uniform boundary shape, every other layer of the stacked ceramic layers extends toward the molding resin.

5. The ceramic stacked semiconductor package of claim 1, wherein, in the inner walls of the junctions having the non-uniform boundary shape, every other layer of the stacked ceramic layers is shortened in a direction away from the molding resin.

6. The ceramic stacked semiconductor package of claim 1, wherein the via-holes are arranged at different positions so as not to overlap each other between the ceramic layers.

7. The ceramic stacked semiconductor package of claim 1, wherein the via-holes have a plurality of different diameters in each ceramic layer.

8. A method of packaging a ceramic stacked semiconductor, the method comprising:
stacking a plurality of ceramic layers to manufacture a stacked body;
forming via-holes through which the ceramic layers are connected to each other;
filling an inside of the stacked body with a molding resin; and
forming inner walls of junctions having a non-uniform boundary shape on junctions between the stacked ceramic layers and the molding resin.

9. The method of claim 8, wherein the forming of the inner walls of the junctions having the non-uniform boundary shape comprises
extending at least one layer of the stacked ceramic layers toward the molding resin.

10. The method of claim 8, wherein the forming of the inner walls of the junctions having the non-uniform boundary shape comprises
shortening at least one layer of the stacked ceramic layers in a direction away from the molding resin.

11. The method of claim 8, wherein the forming of the inner walls of the junctions having the non-uniform boundary shape comprises
extending every other layer of the stacked ceramic layers toward the molding resin.

12. The method of claim 8, wherein the forming of the inner walls of the junctions having the non-uniform boundary shape comprises
shortening every other layer of the stacked ceramic layers in a direction away from the molding resin.

13. The method of claim 8, wherein the forming of the via-holes comprises
arranging the via-holes of the ceramic layers at different positions so as not to overlap each other between the ceramic layers.

14. The method of claim 8, wherein the forming of the via-holes comprises
forming the via-holes having a plurality of different diameters in each ceramic layer.
